(19) United States
(12) Patent Application Publication
(10) Pub. No.: US 2005/0167808 A1
(43) Pub. Date: Aug. 4, 2005

(54) Semiconductor device, its fabrication method and electronic device

(76) Inventors: Masako Sasaki, Kodaira (JP); Kazunari Suzuki, Tokyo (JP); Seiichi Ichihara, Hino (JP); Tomoaki Kudaishi, Kodaira (JP); Hisao Nakamura, Akiruno (JP); Kunihiko Nishi, Kokubunji (JP); Hideki Tanaka, Sagamihara (JP); Yutaka Nakajima, Kodaira (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/092,685

(22) Filed: Mar. 30, 2005

Related U.S. Application Data
(63) Continuation of application No. 10/252,545, filed on Sep. 24, 2002.
Application No. 10/252,545 is a continuation of application No. 09/493,279, filed on Jan. 28, 2000, now abandoned.

(30) Foreign Application Priority Data
Feb. 15, 1999 (JP) 11-035784

(51) Int. Cl. H01L 23/495

(52) U.S. Cl. 257/678

(57) ABSTRACT

A semiconductor device comprising a semiconductor chip having an electrode on a circuit formation surface thereof, a flexible film having a lead attached thereto and electrically connected to said electrode of said semiconductor chip through a bump, a resin for covering said circuit formation surface of said semiconductor chip and a resin film for covering a back surface facing said circuit formation surface of said semiconductor chip.

This application is a continuation of U.S. application Ser. No. 10/252,545, filed Sep. 24, 2002, which, in turn is a continuation of U.S. application Ser. No. 09/493,279, filed Jan. 28, 2000 (now abandoned), the subject matters of which are incorporated herein by reference.

### FIELD OF THE INVENTION

In general, the present invention relates to a semiconductor device and an electronic device having the semiconductor device embedded therein. More particularly, the present invention relates to an effective technology, applicable to a TCP (Tape Carrier Package)-type semiconductor device and an electronic device having the semiconductor device embedded therein.

### BACKGROUND OF THE INVENTION

A TCP-type semiconductor device is a known type of semiconductor device. The TCP-type semiconductor device is manufactured by using a tape carrier for forming leads through etching fabrication carried out on a metallic foil attached to the surface of a flexible film. Thus, in comparison with a semiconductor device manufactured by using a lead frame for forming leads by press fabrication or etching fabrication carried out on a metallic plate, the TCP-type semiconductor device is thin and can have many pins.

The TCP-type semiconductor device has a configuration comprising a semiconductor chip including electrodes formed on a circuit formation surface (or the main surface) of the chip, leads electrically connected to the electrodes of the semiconductor chip, a flexible film for binding the leads and a resin for covering the circuit formation surface of the semiconductor chip. One end of each of the leads is connected to one of the electrodes of the semiconductor chip through a bump while the other end is pulled out to the outside area surrounding the semiconductor chip. The end of each of the leads is connected to one of the electrodes of the semiconductor chip by a thermal-crimping process. The bump is used as a junction material for connecting the end of each of the leads to one of the electrodes of the semiconductor chip. At a stage before connecting the end of each of the leads to one of the electrodes of the semiconductor chip, the bump is formed on the electrode of the semiconductor chip or the end of the lead in advance.

In order to increase the storage capacity of a memory module, on the other hand, TCP-type semiconductor devices each including an embedded DRAM (Dynamic Random Access Memory) are implemented on two parallel overlapping stages on a mounting substrate to form what is known as a stacked-layer-type memory module. Since a stacked-layer-type memory module is implemented by putting TCP-type semiconductor devices proper for a thin configuration on two overlapping stages, it is possible to virtually realize a storage capacity twice that of a memory module implementing a semiconductor device with a package structure in which the entire semiconductor chip is sealed with a resin seal material at about the same thickness. An example of such a semiconductor device with a package structure sealing the entire semiconductor chip with a resin seal material is a TSOP-type semiconductor device.

The stacked-layer-type module implements a plurality of TCP-type semiconductor devices on two parallel overlapping stages on the front and back surfaces (a main surface and another main surface facing each other) of a mounting substrate in a configuration wherein the TCP-type semiconductor devices are covered with metallic cap members. The cap member is typically provided on each of the front and back surfaces of the mounting substrate, being attached to the mounting substrate. There are two types of TCP-type semiconductor device, namely, that for the lower stage and that for the upper stage. The TCP-type semiconductor devices are mounted in a configuration wherein the back surface (the other main surface) facing the circuit formation surface of the semiconductor chip in the TCP-type semiconductor device of either type faces a cap member. Leads of the TCP-type semiconductor device of either type are formed into a gull-wing type which is one of surface mounting types. A lead formed into a gull-wing type comprises a first lead portion extended over the inside and the outside of the semiconductor chip, a second lead portion bent from the first lead portion in the thickness direction of the semiconductor chip and a third lead portion extended from the second lead portion in the same direction as the first lead portion. The third lead portion is used as a connection terminal when the semiconductor device is mounted on the mounting substrate by soldering. The first lead portion of the lead of the TCP-type semiconductor device at the upper stage is pulled outward by a length greater than the first lead portion of the lead of the TCP-type semiconductor device at the lower stage. In addition, the second lead portion of the lead of the TCP-type semiconductor device at the upper stage is longer than the second lead portion of the lead of the TCP-type semiconductor device at the lower stage.

It should be noted that the TCP-type semiconductor device is described in documents such as an issue of Nikkei BP entitled “VLSI Package Technology Part II,” published on May 31, 1993, pages 71 to 103.

The stacked-layer-type memory module implementing TCP-type semiconductor devices at two overlapping stages is described in documents such as an issue of Semiconductor and Integrated Circuit Dev., Hitachi Ltd. entitled “GAIN,” published on Mar. 11, 1997, pages 19 to 20.

As a result of a study of the TCP-type semiconductor device and the stacked-layer-type memory module described above, the inventors of the present invention and others have identified the following problems.

(1) The TCP-type semiconductor device has a configuration wherein the circuit formation surface of the semiconductor chip is covered by a potting resin while the back surface of the semiconductor chip is exposed. Thus, a contraction force is applied to the circuit formation surface of the semiconductor chip due to hardening/contraction of the potting resin. As a result, warps result easily. In addition, since the back surface of the semiconductor chip is exposed, the back surface is prone to injuries.

If an injury is inflicted on the back surface of a semiconductor chip, stress caused by warping generated on the semiconductor chip is concentrated on the injured area and a crack originating from the injury results easily on the semiconductor chip. In general, the semiconductor chip has a configuration comprising a semiconductor substrate made of single-crystal silicon and insulation and wiring layers created on the circuit formation surface of the semiconductor substrate as main components. In order to make the semiconductor device thin, a trend of decreasing the thickness of the semiconductor substrate is adopted. However, the thin semiconductor substrate causes a warp to result easily on the semiconductor chip.

In addition, in order to improve the bonding with the potting resin, in some cases, a surface protection film made of resin is created on the circuit formation surface of the semiconductor chip. In such a semiconductor chip, a warp results even more easily.

Furthermore, in a semiconductor chip including an embedded DRAM, the surface protection film made of resin is made thick in order to enhance the endurance strength against an ray. Thus, in such a semiconductor chip, a warp results even more easily.

Moreover, since a semiconductor chip including an embedded storage circuit system generally has a plane surface with a rectangular shape, a warp results even more easily in such a semiconductor chip. Examples of the storage circuit system are a DRAM, an SRAM (Static Random Access Memory) and an EEPROM (Electrically Erasable Programmable Read Only Memory) which is also called a flash memory.

(2) An injury is also inflicted on the back surface of a semiconductor chip during a fabrication process of the TCP-type semiconductor device as follows. A semiconductor wafer attached to a dicing tape is divided into individual semiconductor chips in a dicing process. Then, each semiconductor chip is thrust in an upward direction by using a thrust-up needle of a pickup apparatus. Subsequently, the semiconductor chip is transported to a process at the next stage or transported to an accommodation tray by using an absorption collet. In this case, thrust-up needle inflicts an injury on the back surface of the semiconductor chip.

In addition, in the case of a semiconductor chip obtained as a result of a dicing process, countless broken pieces of wafer material are generated on the peripheral edges (angles formed by a cross-section surface and the back surface) on the back surface side. In some cases, a broken piece of wafer material is not completely detached, but remains stuck to the circumferential edge. These broken pieces of Si may inflict an injury on the back surface of the semiconductor chip. For example, in a process to form a bump by using a wire-bonding technique on an electrode of a semiconductor chip, the semiconductor chip is mounted on a heat stage. At that time, broken pieces of wafer material stuck to the peripheral edge on the back surface side of the semiconductor chip may fall to the heat stage and the broken pieces of wafer material dropped on the heat stage inflict an injury on the back surface of the semiconductor chip.

In a thermal-crimping process to connect one end of a lead to an electrode of the semiconductor chip through a bump, the semiconductor chip is also mounted on the heat stage. At that time, broken pieces of wafer material stuck to the peripheral edge on the back surface side of the semiconductor chip may fall to the heat stage and the broken pieces of wafer material dropped on the heat stage inflict an injury on the back surface of the semiconductor chip.

When an injury is inflicted on the back surface of a semiconductor chip, a crack may result easily on the semiconductor chip at the time a warp is generated in the semiconductor chip due to hardening/contraction of the potting resin applied to the circuit formation surface of the semiconductor chip as a coat. Such a crack serves as a cause of a decreased yield in the fabrication of TCP-type semiconductor devices.

(3) On the other hand, broken pieces of wafer material dropped on the heat stage may re-attach themselves to the back surface of the semiconductor chip mounted on the heat stage and remain stuck to the back surface till the end of the fabrication of the TCP-type semiconductor device. If such a TCP-type semiconductor device is used in the fabrication of a stacked-layer-type memory module, the broken pieces of wafer material are sandwiched by the back surface of the semiconductor chip and a cap member. When the cap member is pressed in a process to paste a shipping seal to the cap member, a crack originating from a portion with a broken piece of wafer material attached thereto may result. A crack generated in the semiconductor chip serves as a cause of a decreased yield in the fabrication process of the memory module.

It is thus another object of the present invention to provide a technology which is capable of preventing a crack from being generated in a semiconductor chip.

It is a further object of the present invention to provide a technology which is capable of raising the yield of the fabrication process of a semiconductor device.

It is a still further object of the present invention to provide a technology which is capable of raising the yield of the fabrication process of an electronic device.

These features, other objects and new characteristics of the present invention will become more apparent from the following description in the specification with reference to accompanying diagrams.

### SUMMARY OF THE INVENTION

An outline of representative features disclosed in this patent application will be described in a simple manner as follows.

(1) A semiconductor device comprises:

a semiconductor chip having an electrode on a circuit formation surface thereof;
a resin for covering the circuit formation surface of the semiconductor chip; and
a resin film made of thermosetting resin and used for covering a back surface facing the circuit formation surface of the semiconductor chip.
   (2) A semiconductor device comprises:
a semiconductor chip having a surface protection film made of resin and an electrode on a circuit formation surface thereof;
a resin for covering the circuit formation surface of the semiconductor chip; and
a resin film made of thermosetting resin and used for covering a back surface facing the circuit formation surface of the semiconductor chip.
   (3) A semiconductor device comprises:
a semiconductor chip having an electrode on a circuit formation surface thereof;
a flexible film having a lead attached thereto and electrically connected to the electrode of the semiconductor chip through a bump;
a resin for covering the circuit formation surface of the semiconductor chip; and
a resin film made of thermosetting resin and used for covering a back surface facing the circuit formation surface of the semiconductor chip.
   (4) A method of fabricating a semiconductor device comprises:
a process of sticking a resin film made of thermosetting resin on a back surface facing a circuit formation surface of a semiconductor wafer by thermal crimping; and
a process of creating a semiconductor chip by dicing the semiconductor wafer and the resin film, the semiconductor chip having an electrode on a circuit formation surface thereof and the resin film bound to a back surface facing the circuit formation surface of the semiconductor chip.
   (5) A method of fabricating a semiconductor device comprises:
a process of sticking a resin film made of thermosetting resin on a back surface facing a circuit formation surface of a semiconductor wafer by thermal crimping;
a process of creating a semiconductor chip by dicing the semiconductor wafer and the resin film, the semiconductor chip having an electrode on a circuit formation surface thereof and the resin film bound to a back surface facing the circuit formation surface of the semiconductor chip; and
a process of mounting the semiconductor chip on a heat stage and thermally crimping a lead to the electrode of the semiconductor chip through a bump.
   (6) A method of fabricating a semiconductor device comprises:
a process of sticking a resin film made of thermosetting resin on a back surface facing a circuit formation surface of a semiconductor wafer by thermal crimping;
a process of creating a semiconductor chip by dicing the semiconductor wafer and the resin film, the semiconductor chip having an electrode on a circuit formation surface thereof and the resin film bound to a back surface facing the circuit formation surface of the semiconductor chip; and
a process of mounting the semiconductor chip on a heat stage and creating a bump on the electrode of the semiconductor chip by using a wire bonding technique.
   (7) A method of fabricating a semiconductor device comprises:
a process of sticking a resin film made of thermosetting resin on a back surface facing a circuit formation surface of a semiconductor wafer by thermal crimping;
a process of creating a semiconductor chip by dicing the semiconductor wafer and the resin film, the semiconductor chip having an electrode on a circuit formation surface thereof and the resin film bound to a back surface facing the circuit formation surface; and
a process of applying resin to the circuit formation surface of the circuit formation surface of the semiconductor chip.
   (8) An electronic device comprises:
a semiconductor device having:
   a semiconductor chip having an electrode on a circuit formation surface thereof;
   a resin for covering the circuit formation surface of the semiconductor chip; and
   a resin film for covering a back surface facing the circuit formation surface of the semiconductor chip;
a mounting substrate on which the semiconductor device is mounted; and
a cap member attached to the mounting substrate so as to cover the semiconductor device,
wherein the semiconductor device is mounted on the mounting substrate in a posture with the back surface of the semiconductor chip facing the cap member.
   (9) An electronic device comprises:
a semiconductor device having:
   a semiconductor chip having an electrode on a circuit formation surface thereof;
   a flexible film having a lead attached thereto and electrically connected to the electrode of the semiconductor chip through a bump;
   a resin for covering the circuit formation surface of the semiconductor chip; and
   a resin film for covering a back surface facing the circuit formation surface of the semiconductor chip;
a mounting substrate on which the semiconductor device is mounted; and
a cap member attached to the mounting substrate so as to cover the semiconductor device,
wherein the semiconductor device is mounted on the mounting substrate in a posture with the back surface of the semiconductor chip facing the cap member.

### BRIEF DESCRIPTION OF THE DRAWINGS

FIG. 1 is a diagram showing a top-view of a TCP-type semiconductor device implemented by the first embodiment;

FIG. 2 is a diagram showing a cross section of the device shown in FIG. 1;

FIG. 3 is a diagram showing an enlarged portion of the cross section shown in FIG. 2;

FIG. 4 is a diagram showing a top-view of a semiconductor wafer from which semiconductor devices each implemented by the first embodiment are fabricated;

FIG. 5 is a diagram showing a cross-sectional view of a portion of the semiconductor wafer from which semiconductor devices each implemented by the first embodiment are fabricated;

FIG. 6 is also a diagram showing a cross-sectional view of a portion of the semiconductor wafer from which semiconductor devices each implemented by the first embodiment are fabricated;

FIG. 7 is also a diagram showing a cross-sectional view of a portion of the semiconductor wafer from which semiconductor devices each implemented by the first embodiment are fabricated;

FIG. 8 is a diagram showing the configuration of a film attaching apparatus used in the fabrication of semiconductor devices each implemented by the first embodiment;

FIG. 9 is a diagram showing a cross-sectional view of a state of a diced semiconductor wafer in the fabrication of semiconductor devices each implemented by the first embodiment;

FIG. 10 is a diagram showing a cross section of an enlarged portion of the wafer shown in FIG. 9;

FIG. 11 is a diagram showing a cross-sectional view of a state of a picked-up semiconductor chip in the fabrication of semiconductor devices each implemented by the first embodiment;

FIG. 12 is a diagram showing a cross-sectional view of a state of creation of a bump in the fabrication of a semiconductor device implemented by the first embodiment;

FIG. 13 is a diagram showing a cross-sectional view of a state of a semiconductor chip mounted on a heat stage in the fabrication of a semiconductor device implemented by the first embodiment;

FIG. 14 is a diagram showing a cross-sectional view of a connection state in the fabrication of a semiconductor device implemented by the first embodiment;

FIG. 15 is a diagram showing a cross-sectional view of a marking state in the fabrication of a semiconductor device implemented by the first embodiment;

FIG. 16 is a diagram showing a top-view of the configuration of a memory module in which the semiconductor device implemented by the first embodiment is embedded;

FIG. 17 is a diagram showing a cross-sectional view of the configuration shown in FIG. 16;

FIG. 18 is a diagram showing a top-view of a TCP-type semiconductor device implemented by a second embodiment of the present invention;

FIG. 19 is a diagram showing a cross section of the device shown in FIG. 18;

FIG. 20 is a diagram showing a top-view of the configuration of a CF card including the semiconductor device implemented by the second embodiment;

FIG. 21 is a diagram showing a cross-sectional view of the configuration of a BAG-type semiconductor device implemented by a third embodiment of the present invention; and

FIG. 22 is a diagram showing a cross-sectional view of the configuration of a CSP-type semiconductor device implemented by a fourth embodiment of the present invention.

### DETAILED DESCRIPTION OF PREFERRED EMBODIMENTS

Some preferred embodiments of the present invention will be described below in detail with reference to the drawings. It should be noted that, in all of the views referred to in the explanation of the embodiments of the present invention, identical functions are denoted by the same reference numeral and will be explained only once.

### First Embodiment

The embodiment is exemplified by an example of applying the present invention to a TCP-type semiconductor device and a memory module (or an electronic device) embedding the semiconductor device which is fabricated by using a tape carrier with a lead formed by etching a metallic foil pasted on the surface of a flexible film. It should be noted that the technology for fabricating a TCP-type semiconductor device is also referred to as a TAB (Tape Automated Bonding) technology, which is a name applied to an assembly means employed in the technology.

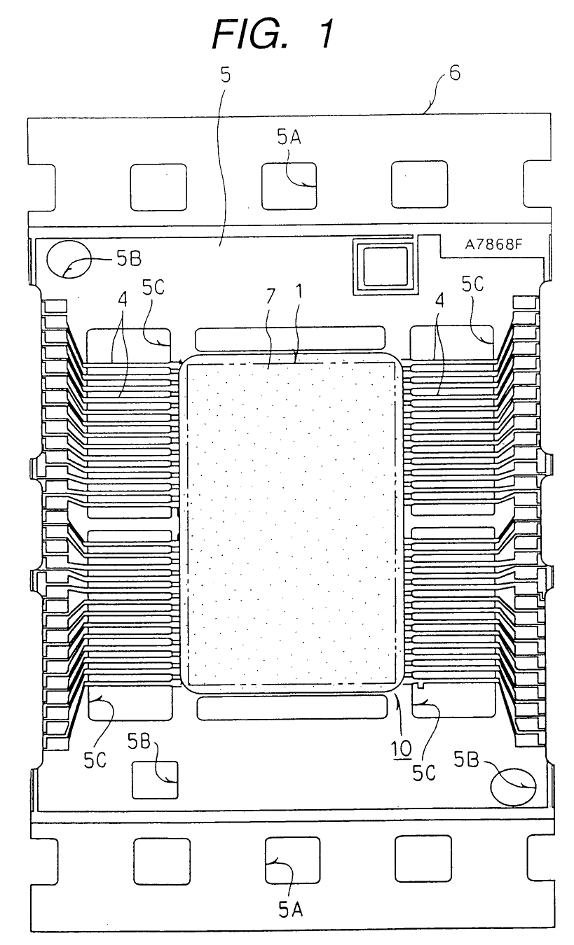

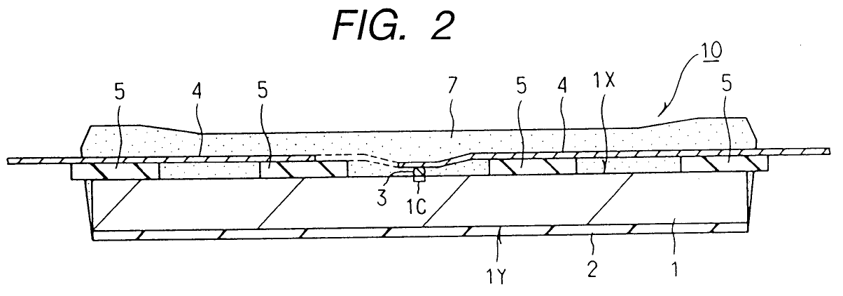

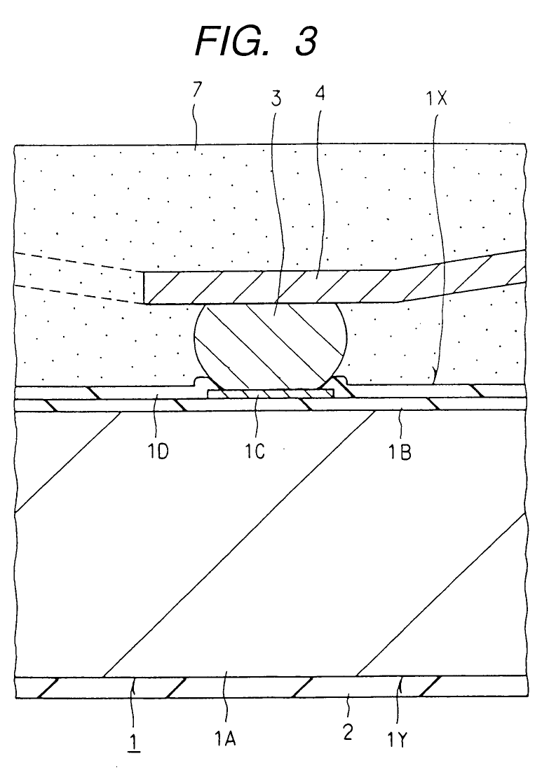

FIG. 1 is a diagram showing a top-view of a semiconductor device implemented by the first embodiment of the present invention. FIG. 2 is a diagram showing a cross section of the device shown in FIG. 1. FIG. 3 is a diagram showing an enlarged portion of the cross section shown in FIG. 2.

As shown in FIGS. 1 and 2, the TCP-type semiconductor device 10 implemented by the embodiment has a configuration comprising main components such as a semiconductor chip 1, a resin 7 for covering a circuit formation surface 1X of the semiconductor chip 1 and a tape carrier 6 with a plurality of leads 4 created on the surface of a flexible film 5.

The tape carrier 6 has a configuration wherein a unit lead pattern comprising a plurality of leads 4 is created repeatedly in the longitudinal direction of the tape carrier 6 on the surface of the flexible film 5 which has a fixed width. FIG. 1 shows an area for one lead pattern. The leads 4 are formed by pasting a metallic foil on the surface of the flexible film 5 through a bonding agent and then etching the metallic foil. The flexible film 5 is typically made of a resin of a polyimide group having a thickness of 75 μm. As for the metallic foil, for example, a copper foil with a thickness of 35 μm is used.

On both sides of the flexible film 5, perforation holes 5A used for moving the tape carrier 6 are provided at fixed intervals. In addition, positioning holes 5B used for positioning the flexible film 5 during a fabrication process are provided also on both sides of the flexible film 5.

The top-view shape of the semiconductor chip 1 is rectangular, having typical dimensions of 8.4×13.4. The semiconductor chip 1 is provided with an embedded DRAM having a typical storage capacity of 64 megabits as a storage circuit system.

The leads 4 are divided into two lead groups. Leads 4 in one of the two lead groups are provided along one of the two long sides of the semiconductor chip 1 facing each other and leads 4 in the other lead group are provided along the other long side of the semiconductor chip 1. One end of each of the leads 4 is extended to the circuit formation surface 1X through the flexible film 5. The other end of each of the leads 4 is pulled out to the outside of the external circumference of the semiconductor chip 1. The other end of each of the leads 4 is extended to cross a long hole 5C provided on the flexible film 5 outside of the semiconductor chip 1. In this way, the edge on the other side is supported by the flexible film 5.

An electrode 1C is formed at the center of the circuit formation surface 1X of the semiconductor chip 1. A plurality of such electrodes 1C are laid out in the long-side direction of the semiconductor chip 1.

One end of each of the leads 4 is electrically and mechanically connected to one of the electrodes 1C of the semiconductor chip 1 through a bump 3. Typically, the bump 3 is an Au bump created on the electrode 1C of the semiconductor chip 1 by using a ball bonding technique. It should be noted, however, that the bump 3 is not restricted to such a bump. The end of each of the leads 4 is connected to the bump 3 in a thermal-crimping process.

As shown in FIG. 3, the semiconductor chip 1 has a configuration comprising main components such as a semiconductor substrate 1A typically made of single-crystal silicon, a multisublayer wiring layer 1B composed of a plurality of stages of insulation and wiring sublayers stacked on each other on the circuit formation surface of the semiconductor substrate 1A and a surface protection film 1D formed to cover the multisublayer layer 1B. Typically, the surface protection film 1D is made of resin of the polyimide group which is capable of improving the endurance strength against an•ray and strengthening the bonding with the resin 7. The surface protection film 1D employed in this embodiment has a typical thickness of about 10 μm. Thus, this surface protection film 1D is thicker than a surface protection film of a semiconductor chip including an embedded logic-circuit system. In the case of a logic-circuit system, the surface protection film has a typical thickness of about 2.5 μm. The thickness of the semiconductor substrate 1A exhibits a trend of decreasing with a reduced thickness of the TCP-type semiconductor device 10. In this embodiment, the thickness is about 280 μm.

The electrode 1C is created on the uppermost wiring layer of the multisublayer layer 1B of the semiconductor chip 1. Typically, it is created from a metallic film which is made of typically an aluminum (Al) film or an aluminum alloy film. The bump 3 is connected to the electrode 1C through a bonding opening provided on the surface protection film 1D.

The resin 7 is created by first coating the surface protection surface 1X of the semiconductor chip 1 with thermosetting resin of an epoxy group which is doped typically with-an organic solvent by using a bonding technique and then hardening the thermosetting resin by conducting a heat treatment process. In a word, the resin 7 is made of a thermosetting resin of the epoxy group. The thickness of the resin 7 is typically in the range 0.1 to 0.25 mm on the electrode 1C of the semiconductor chip 1.

A resin film 2 is bonded to a back surface 1Y facing the circuit formation surface 1X of the semiconductor chip 1 so as to cover the back surface 1Y. By bonding the resin film 2 to the back surface 1Y of the semiconductor chip 1 so as to cover the back surface 1Y in this way, the back surface 1Y of the semiconductor chip 1 is protected by the resin film 2. Thus, no injury is inflicted on the back surface 1Y of the semiconductor chip 1. As a result, even if a warp is generated on the semiconductor chip 1 due to a contraction force applied to the circuit formation surface 1X of the semiconductor chip 1 because of hardening/contraction of the resin 7 covering the circuit formation surface 1X of the semiconductor chip 1, it is possible to prevent a crack from originating from an injury to be generated in the semiconductor chip 1. In particular, with the thickness of the semiconductor 1A reduced in order to make the TCP-type semiconductor device 10 thin as is the case with this embodiment, with the top-view shape of the semiconductor chip 1 made rectangular, with the surface protection film 1D made of resin of the polyimide group in order to improve the bonding with the resin 7 or with the thickness of the surface protection film 1D increased in order to improve the endurance strength against an•ray, a warp is generated more easily in the semiconductor chip 1 so that it is important to prevent an injury from being inflicted on the back surface 1Y of the semiconductor chip 1.

The resin film 2 is typically made of a thermosetting resin of the epoxy group. As will be described later in detail, the resin film 2 is bonded and attached in a thermal-crimping process. Thus, a contraction force generated by hardening/contraction of the resin film 2 is applied to the back surface 1Y of the semiconductor chip 1. By creating the resin film 2 from a thermosetting resin in this way, a contraction force generated by hardening/contraction of the resin film 2 is applied to the back surface 1Y of the semiconductor chip 1. Thus, a warp can be prevented from being generated in the semiconductor chip 1 due to hardening/contraction of the resin 7 covering the circuit formation surface 1X of the semiconductor chip 1. By increasing the thickness of the resin film 2, the contraction force applied to the back surface IY of the semiconductor chip 1 can be increased. However, an excessively thick resin film 2 will become a hindrance to efforts to make the TCP-type semiconductor device 10 thin. On the other hand, an excessively thin resin film 2 will result in a small effect of suppressing generation of a warp in the semiconductor chip 1. It is thus desirable to employ a resin film 2 thinner than the resin 7 on the electrode 1C of the semiconductor chip 1. In this embodiment, the resin film 2 is created to have a thickness of about 25 μm.

In addition, by creating the resin film 2 from a thermosetting resin of the epoxy group in this way, the bonding of the thermosetting resin of the epoxy group to the silicon is strengthened so that the resin film 2 becomes difficult to peel off.

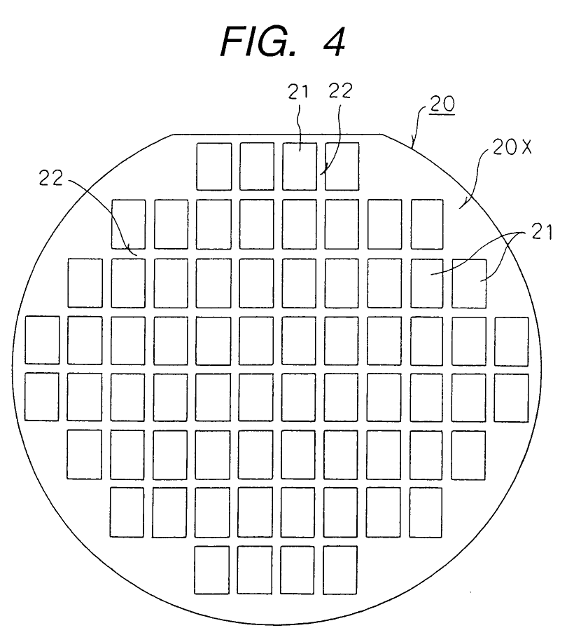

Next, a method to fabricate the TCP-type semiconductor device 10 will be explained with reference to FIGS. 4 to 15.

FIG. 4 is a diagram showing a top-view of a semiconductor wafer from which semiconductor devices are fabricated;

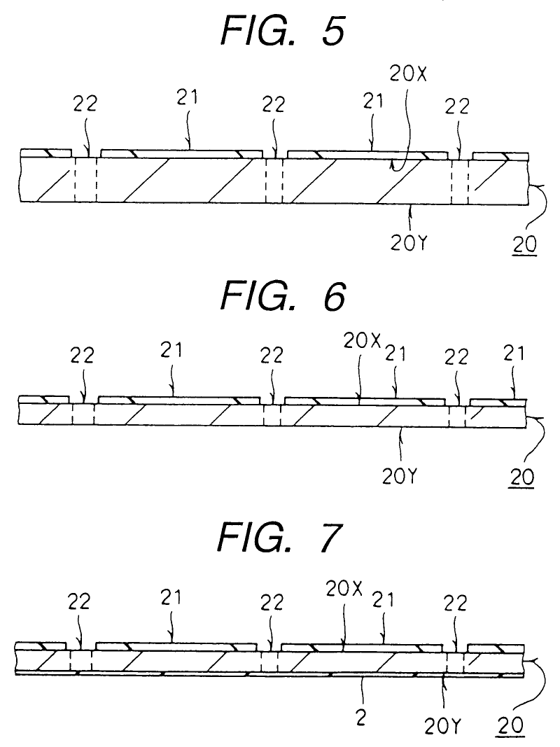

FIGS. 5 to 7 are each a diagram showing a cross-sectional view of a portion of the semiconductor wafer from which semiconductor devices are fabricated;

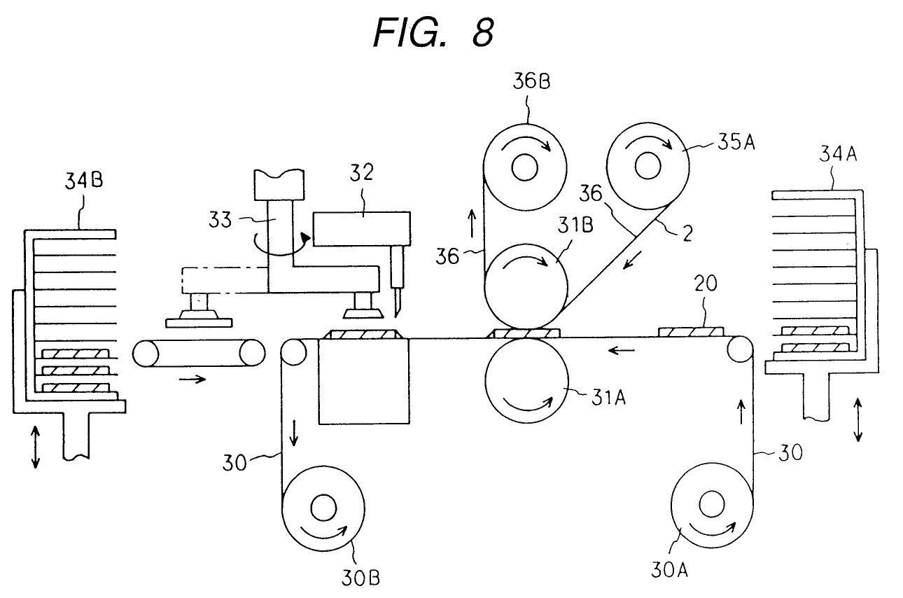

FIG. 8 is a diagram showing the configuration of a film attaching apparatus used in the fabrication of semiconductor devices;

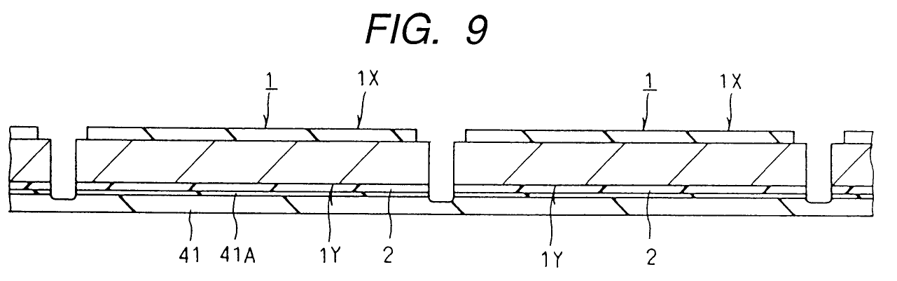

FIG. 9 is a diagram showing a cross-sectional view of a state of a diced semiconductor wafer in the fabrication of semiconductor devices;

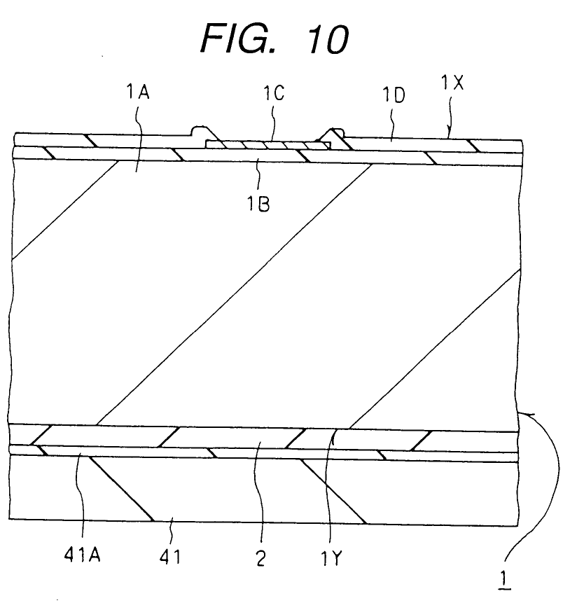

FIG. 10 is a diagram showing a cross section of an enlarged portion of the wafer shown in FIG. 9;

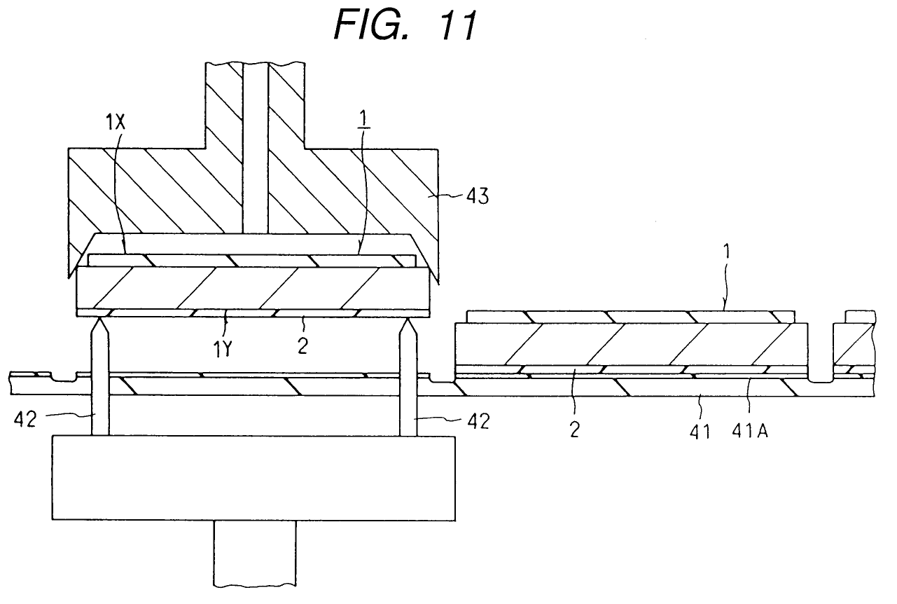

FIG. 11 is a diagram showing a cross-sectional view of a state of a picked-up semiconductor chip in the fabrication of a semiconductor device;

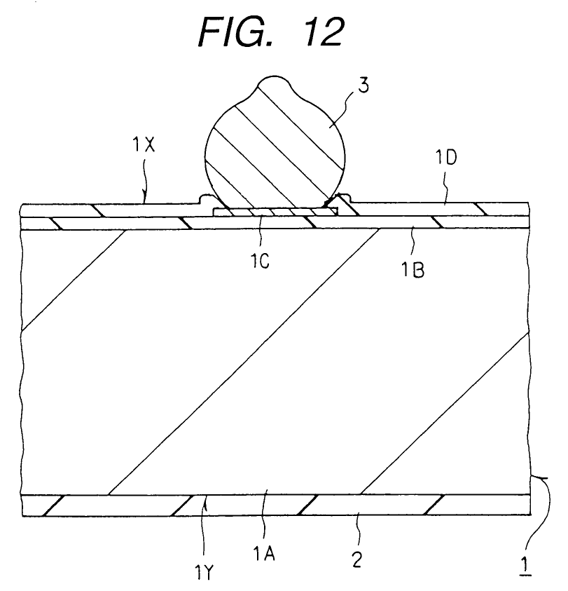

FIG. 12 is a diagram showing a cross-sectional view of a state of creation of a bump in the fabrication of a semiconductor device;

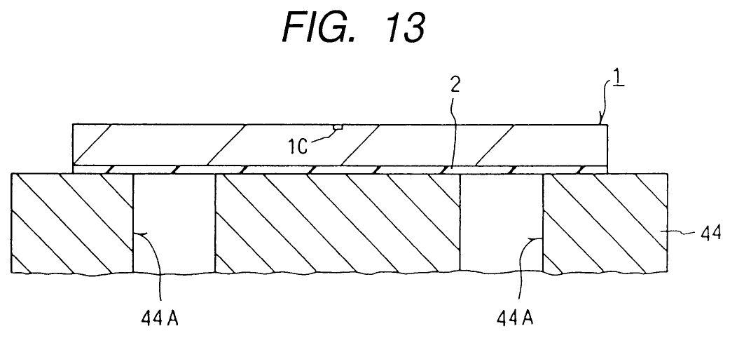

FIG. 13 is a diagram showing a cross-sectional view of a state of a semiconductor chip mounted on a heat stage in the fabrication of a semiconductor device;

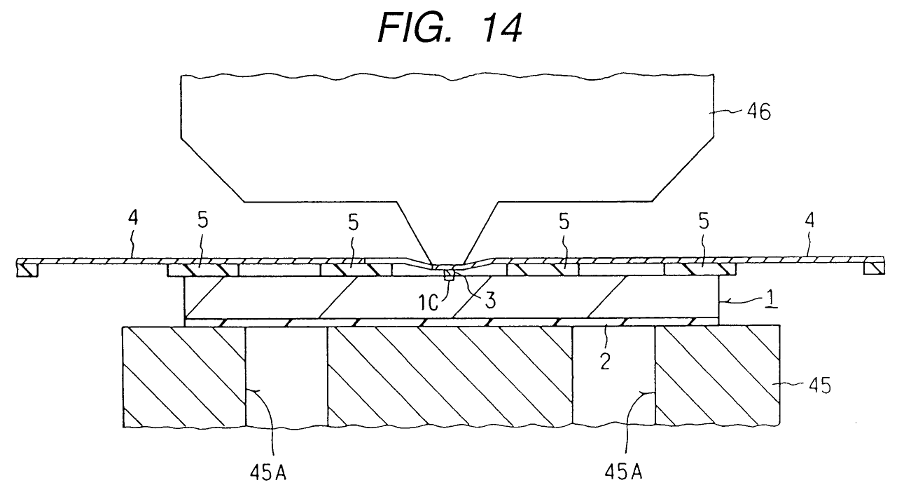

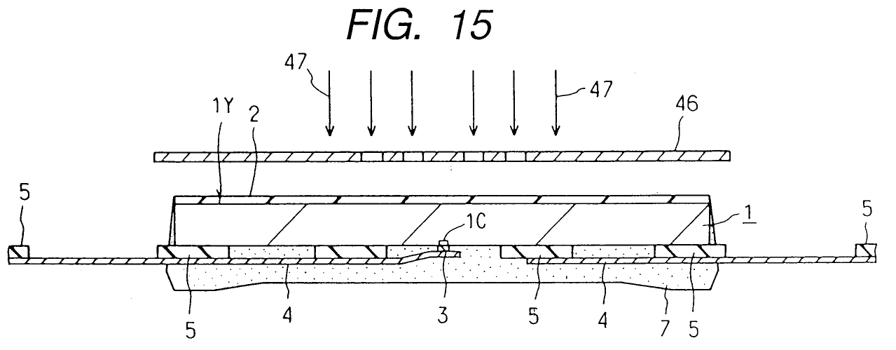

FIG. 14 is a diagram showing a cross-sectional view of a connection state in the fabrication of a semiconductor device; and

FIG. 15 is a diagram showing a cross-sectional view of a marking state in the fabrication of a semiconductor device.

First of all, a semiconductor wafer (semiconductor substrate) 20 made of single-crystal silicon with a typical thickness of 720 μm is prepared.

Next, a semiconductor device, an insulation layer, a wiring layer, an electrode 1C, a surface protection film 1D, a bonding opening and other components are created on the circuit formation surface 20X of the semiconductor wafer 20. In essence, a plurality of DRAMS each serving as a uniform storage circuit system are created to form a matrix. A plurality of chip formation areas 21 are laid out in such a way as to be separated from each other by dicing areas or cutting areas 22 which are diced to break up the semiconductor wafer. The processes up to this point are shown in FIGS. 4 and 5.

Next, the back surface 20Y facing the circuit formation surface 20X of the semiconductor wafer 20 is ground to reduce the thickness of the semiconductor wafer 20. In this embodiment, the back surface 20Y is ground till the thickness of the semiconductor wafer 20 is reduced to typically about 280 μm. The process up to this point is shown in FIG. 6.

Next, as shown in FIG. 7, a resin film 2 is pasted to the back surface 20Y of the semiconductor wafer 20. The resin film 2 is stuck by using a film sticking apparatus shown in FIG. 8.

The film sticking apparatus has a configuration comprising:
a carrier-tape supplying unit for sequentially supplying a carrier tape 30 from a reel 30A;
a carrier-tape accommodating unit for winding the carrier tape 30 around a reel 30B;
a sticking unit for sticking a resin film 2 on the back surface of the semiconductor wafer 20 by thermal crimping using a heating roller 31A and a heating roller 31B;
a cutting unit for cutting off a resin film by using a cutter 32 along a contour of the semiconductor wafer 20;
a wafer conveying unit for conveying a semiconductor wafer 20 following completion of the cutting process by using an absorption arm 33;
a wafer supplying unit for supplying a semiconductor wafer 20 from a cassette 34A to the carrier tape 30;
a wafer accommodating unit for accommodating a semiconductor wafer 20, which has been conveyed by the absorption arm 33, in a cassette 34B;
a film supplying unit for sequentially supplying a resin film 2 and a spacer tape 36 from a reel 35A to the sticking unit; and
a spacer-tape accommodating unit for sequentially winding the spacer tape 36, which has been peeled off from the resin film 2, around a reel 35B.

In this film sticking apparatus, the resin film 2 can be stuck into a real bonding or a tentative binding. In the case of tentative binding, the resin films 2 are stuck one piece after another or in multiple-piece units. This process produces a state of a thermally hardened resin film 2 bound to the back surface of the semiconductor wafer 20.

Next, an electrical test (not shown in the figure) is conducted to determine whether or not the storage circuit system of each chip operates as desired. Results of the test can be used for determining whether each chip is good or bad and for determining the grade of electrical characteristics such as the operating frequency.

Then, the semiconductor wafer 20 is mounted on an adhesion layer 41A of a dicing sheet 41. The semiconductor wafer 20 is mounted in a posture with the circuit formation surface 20X of the semiconductor wafer 20 facing upward.

Subsequently, the semiconductor wafer 20 and the resin film 2 are diced by using a dicing apparatus, to split the semiconductor wafer 20 and the resin film 2 into chip formation areas 21 which each include a semiconductor chip 1. As shown in FIGS. 9 and 10, the semiconductor chip 1 has a circuit system (DRAM) on the circuit formation surface 1X, a multisublayer wiring layer 1B, an electrode 1C, a surface protection film 1D, a bonding opening, etc. The resin film 2 is stuck on the back surface 1Y of the semiconductor chip 1. At that time, a broken piece of wafer material has not been completely detached from the circumferential edge of the back surface 1Y (an angle formed by a cross section and the back surface 1Y) of the semiconductor chip 1 obtained from the dicing process. Even if such a piece exists, the piece is held by the resin film 2 to prevent the piece from falling to a heat stage for mounting the semiconductor chip 1 in a subsequent process.

In addition, since the resin film 2 is not stiff (soft) in comparison with the semiconductor substrate 1A made of silicon, the semiconductor wafer 20 can be diced with ease, and a resin film 2 matching the external size of the semiconductor chip 1 can also be formed with ease.

Next, as shown in FIG. 11, the semiconductor chip 1 is thrust up by using a thrust-up needle 42 of a pickup apparatus below a dicing sheet 41 causing movement of the semiconductor chip 1 in the upward direction. Subsequently, the semiconductor chip 1 is transported to a process at the next stage by using an absorption collet 43 of the pickup apparatus. At that time, since the back surface 1Y of the semiconductor chip 1 is protected by the hardened resin film 2, the tip of the thrust-up needle 42 is not brought into contact with the back surface 1Y of the semiconductor chip 1, but is brought into contact with the resin film 2. As a result, an injury can be prevented from being inflicted on the back surface 1Y of the semiconductor chip 1 by the thrust-up needle 42 as it is brought into contact with the resin film 2.

Then, as shown in FIG. 12, a bump 3 is created on the electrode 1C of the semiconductor chip 1 by adopting the ball-bonding technique. According to a ball-bonding technique, a ball created at the tip of a metallic wire made typically of Au is bound to an electrode of a semiconductor chip and then a bump is formed by cutting off the metallic wire from the ball. Thus, the semiconductor chip 1 is mounted on the heat stage 44 and is firmly absorbed thereby as shown in FIG. 13. The semiconductor chip 1 firmly absorbed by the heat stage 44 is heated by the stage 44. At that time, there is a concern that the resin film 2 will be bound to the heat stage 44. For this reason, the mounting surface of the heat stage 44 is subjected to a fluorine coating process in advance. In this way, it is possible to prevent the resin film 2 from being bound to the heat stage 44. In addition, by increasing the area of an absorption hole 44A in the top-view direction, the contact area between the heat stage 44 and the resin film 2 can be decreased. As a result, it is also possible to prevent the resin film 2 from being bound to the heat stage 44.

In addition, when the semiconductor chip 1 is mounted on the heat stage 44, a broken piece of wafer material which is not completely detached from the circumferential edge of the back surface 1Y of the semiconductor chip 1 is held by the resin film 2 and thus is prevented from falling down to the heat stage 44. Thus, the back surface 1Y of the semiconductor chip 1 can be prevented from being injured by a piece of wafer material that has dropped on the heat stage 44.

Furthermore, since the back surface of the semiconductor chip 1 is protected by the resin film 2, the back surface 1Y of the semiconductor chip 1 will not be injured by a broken piece of wafer material dropped on the heat stage 44 even if such a piece exists.

Moreover, since a broken piece of wafer material can be prevented from falling down to the heat stage 44, such a broken piece will not be re-stuck on the back surface 1Y of the semiconductor chip 1 when the semiconductor chip 1 is mounted on the heat stage 44.

Next, as shown in FIG. 14, one of the ends of the lead 4 is connected to the electrode 1C of the semiconductor chip 1 through the bump 3 by a thermal-crimping process using a bonding tool 46. In this process, the semiconductor chip 1 is mounted on a heat stage 45 to be firmly absorbed thereby. The firmly absorbed semiconductor chip 1 is heated by the heat stage 45. At that time, there is a concern that the resin film 2 will be bound to the heat stage 45. For this reason, the mounting surface of the heat stage 45 is subjected to a fluorine coating process in advance. In this way, it is possible to prevent the resin film 2 from being bound to the heat stage 45. In addition, by increasing the area of an absorption hole 45A in the top-view direction, the contact area between the heat stage 45 and the resin film 2 can be decreased. As a result, it is also possible to prevent the resin film 2 from being bound to the heat stage 45.

In addition, when the semiconductor chip 1 is mounted on the heat stage 45, a broken piece of wafer material which is not completely detached from the circumferential edge of the back surface 1Y of the semiconductor chip 1 is held by the resin film 2 and thus is prevented from falling down to the heat stage 45. Thus, the back surface 1Y of the semiconductor chip 1 can be prevented from being injured by a piece of wafer material that has dropped on the heat stage 45.

Furthermore, since the back surface of the semiconductor chip 1 is protected by the resin film 2, the back surface 1Y of the semiconductor chip 1 will not be injured by a broken piece of wafer material dropped on the heat stage 45 even if such a piece exists.

Moreover, since a broken piece of wafer material can be prevented from falling down to the heat stage 45, such a broken piece will not be re-stuck on the back surface 1Y of the semiconductor chip 1 when the semiconductor chip 1 is mounted on the heat stage 45.

Then, a resin 7 for covering the circuit formation surface 1X of the semiconductor chip 1 is formed. The resin 7 is created by first coating the surface protection surface 1X of the semiconductor chip 1 with thermosetting resin of an epoxy group which is doped typically with an organic solvent by using a bonding technique and then by hardening the thermosetting resin by conducting a heat-treatment process. In this process, a contraction force generated by hardening/contraction of the resin 7 is applied to the circuit formation surface 1X of the semiconductor chip 1, resulting in a warp in the semiconductor chip 1 in some cases. Since there is no injury inflicted on the back surface 1Y of the semiconductor chip 1, however, it is possible to prevent generation of a crack from originating from an injury in the semiconductor chip 1.

In addition, the resin film 2 is bonded to the back surface 1Y of the semiconductor chip 1 to cover the back surface IY so that a contraction force generated by hardening/contraction of the resin film 2 is applied to the back surface 1Y. Thus, it is possible to prevent a warp from being generated in the semiconductor chip 1 by hardening/contraction of the resin 7 covering the circuit formation surface 1X of the semiconductor chip 1.

Subsequently, identification marks are formed on the resin film 2 on the back surface 1Y of the semiconductor chip 1 by adopting a laser marking technique. The identification marks include the name of the product, the name of the manufacturer, the type of the product and the manufacturing lot number. More specifically, as shown in FIG. 15, a mask 46 with a mark pattern formed thereon is used. A laser beam 47 is radiated to the resin film 2 through the mask 46. In this way, the surface of the resin film 2 is etched out by the laser beam 47 radiated thereto to form an identification mark. According to the laser marking technique, an identification mark is formed by cutting out a portion to which a laser beam is radiated. For this reason, there will hardly be a problem caused by a disappearing laser mark. It is difficult, however, to form an identification mark by using the laser marking technique on the back surface 1Y of the semiconductor chip 1, that is, the semiconductor substrate. This is because, since an injury is inflicted on the semiconductor substrate, a crack is generated easily in the semiconductor chip 1. Thus, while it is naturally difficult to form an identification mark on the back-surface side of the semiconductor chip 1, it is now possible to form an identification mark on the side of the back surface 1Y of the semiconductor chip 1 by virtue of the resin film 2 provided on the back surface 1Y of the semiconductor chip 1 as is the case with this embodiment.

At the end of this process, the fabrication of the TCP-type semiconductor device 10 shown in FIGS. 1, 2 and 3 is all but completed.

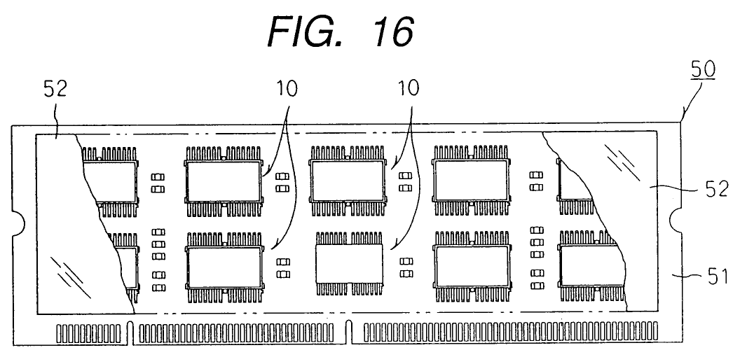

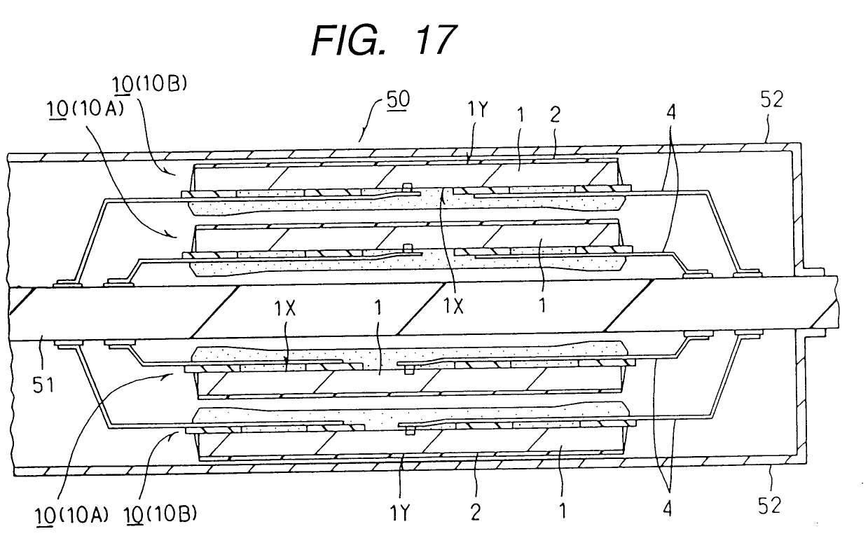

The following description is directed to a memory module (or an electronic device) in which the TCP-type semiconductor device 10 is embedded as seen in FIGS. 16 and 17.

FIG. 16 is a diagram showing a top-view model of the configuration of a memory module in which the TCP-type semiconductor device 10 is embedded in a simple and plain manner. FIG. 17 is a diagram showing a cross-sectional model of the configuration shown in FIG. 16.

As shown in FIGS. 16 and 17, the memory module 50 provided by the embodiment has a configuration wherein TCP-type semiconductor devices 10 are implemented on two parallel overlapping stages on the front and back surfaces (that is, a main surface and another main surface facing each other) of a mounting substrate 51 and these TCP-type semiconductor devices 10 are covered by metallic cap members 52. The metallic cap members 52 are provided on the front and back surfaces of the mounting substrate 51, being attached to the mounting substrate 51. There are two kinds of TCP-type semiconductor devices 10, namely, those for the upper stage and those for the lower stage. The two kinds of TCP-type semiconductor devices 10 are mounted in a posture so that the back surface 1Y facing the circuit formation surface 1X of each of the semiconductor chips 1 is exposed to the cap member 52. Leads 4 of the TCP-type semiconductor device 10 of either type are formed into a gull-wing type, which is one of the known surface mounting types. A lead 4 formed into a gull-wing type comprises a first lead portion extended over the inside and the outside of the semiconductor chip 1, a second lead portion bent from the first lead portion in the thickness direction of the semiconductor chip 1 and a third lead portion extended from the second lead portion in the same direction as the first lead portion. The third lead portion is used as a connection terminal when the TCP-type semiconductor device 10 is mounted on the mounting substrate 51 by soldering. The first lead portion of the lead 4 of the TCP-type semiconductor device 10B at the upper stage is pulled outward by a length greater than the first lead portion of the lead 4 of the TCP-type semiconductor device 10A at the lower stage. In addition, the second lead portion of the lead 4 of the TCP-type semiconductor device 10B at the upper stage is longer than the second lead portion of the lead 4 of the TCP-type semiconductor device 10A at the lower stage.

Next, a method of fabricating the memory module 50 will be explained with reference to FIGS. 1, 16 and 17.

First of all, the TCP-type semiconductor 10 shown in FIG. 1 is prepared.

Next, one end of each of the leads 4 is cut off and then the lead 4 is formed into a Gull-wing type. Subsequently, the flexible film 5 is cut out and the TCP-type semiconductor device 10 is removed from the tape carrier 6. In this way, a TCP-type semiconductor device 10A for the lower stage and a TCP-type semiconductor device 10B for the upper stage are formed.

Then, in a state with the TCP-type semiconductor device 10A for the lower stage and the TCP-type semiconductor device 10B for the upper stage overlapping each other, the third-portions of their leads 4 are bonded to the electrode of the mounting substrate 51 by soldering, whereas the TCP-type semiconductor device 10A for the lower stage and the TCP-type semiconductor device 10B for the upper stage are mounted on the front and back surfaces of the mounting substrate 51.

Next, the cap members 52 are attached to the mounting substrate 51 to cover the TCP-type semiconductor devices 10 and, then, a shipping seal is pasted to the cap member 52 to all but complete the memory module 50. When the cap member 52 is pressed in a process to paste the shipping seal to the cap member 52, generation of a crack is prevented from originating from a portion with a broken piece of Si attached thereto since such a piece is prevented from being re-stuck on the back surface 1Y of the semiconductor chip 1.

The embodiment described above provides effects listed as follows.

(1) In the TCP-type semiconductor device 10, a resin film 2 is bound to the back surface 1Y of the semiconductor chip 1 to cover the back surface 1Y. In such a configuration, the back surface 1Y of the semiconductor chip 1 is protected by the resin film 2. Thus, no injury is inflicted on the back surface 1Y of the semiconductor chip 1. As a result, it is possible to prevent generation of a crack from originating from such an injury even if a warp is generated in the semiconductor chip 1 due to a contraction force applied to the circuit formation surface 1X of the semiconductor chip 1 because of hardening/contraction of the resin 7 covering the circuit formation surface 1X of the semiconductor chip 1.

(2) In the TCP-type semiconductor device 10, the resin film 2 is formed from thermosetting resin of the epoxy group. In this configuration, since a contraction force is applied to the rear surface 1Y of the semiconductor chip 1 due to hardening/contraction of the resin film 2, it is possible to prevent a warp from being generated in the semiconductor chip 1 due to hardening/contraction of the resin 7 covering the, circuit formation surface 1X of the semiconductor chip 1.

In addition, by forming the resin film 2 from thermosetting resin of the epoxy group, the resin film 2 is difficult to peel off since the thermosetting resin of the epoxy group exhibits a strong adhesive power with silicon.

(3) In the fabrication of the TCP-type semiconductor device 10, a resin film 2 made of thermosetting resin of the epoxy group is stuck on a back surface 20Y facing a circuit formation surface 20X of the semiconductor wafer 20 in a thermal-crimping process. Then, the semiconductor wafer 20 and the resin film 2 are diced to produce semiconductor chips 1 each having a surface protection film 1D and an electrode 1C on a circuit formation surface 1X thereof as well as the resin film 2 attached to a back surface 1Y facing the circuit formation surface 1X. In this configuration, it is possible that broken pieces of wafer material may not be completely detached from the back surface 1Y, hence, being stuck on the peripheral edges (angles formed by a cross-section surface and the back surface) on the back surface 1Y of the semiconductor chip 1 obtained as a result of the dicing process. Since such broken pieces are kept by the resin film 2, however, the resin film 2 prevents them from falling to things such as a heat stage on which the semiconductor chip 1 is mounted in a subsequent process.

In addition, since the broken pieces can be prevented from falling to things such as the heat stage, it is also possible to prevent dropped pieces from inflicting an injury upon the back surface 1Y of the semiconductor chip 1 during a process of forming a bump 3 on the electrode 1C of the semiconductor chip 1 by using a wire bonding technique and a thermal-crimping process to attach one end of the lead 4 to the electrode 1C of the semiconductor chip 1. Furthermore, since the rear surface 1Y of the semiconductor chip 1 is protected by the resin film 2, no injury will be inflicted on the rear surface 1Y of the semiconductor chip 1 even if a broken piece falls down. Thus, no injury will be inflicted on the rear surface 1Y of the semiconductor chip 1 even if a warp is generated in the semiconductor chip 1 due to a contraction force applied to the circuit formation surface 1X of the semiconductor chip 1 because of hardening/contraction of the resin 7 covering the circuit formation surface 1X of the semiconductor chip 1. As a result, it is possible to prevent generation of a crack from originating from such an injury. Therefore, the yield of the fabrication of the TCP-type semiconductor devices 10 can be increased.

Moreover, since the resin film 2 is not stiff in comparison with the semiconductor substrate 1A made of silicon, the semiconductor wafer 20 can be diced with ease, and a resin film 2 matching the external size of the semiconductor chip 1 can also be formed with ease.

In addition, a resin film 2 is bound to the back surface 1Y of the semiconductor chip 1 to cover the back surface 1Y. In such a configuration, a contraction force is applied to the back surface 1Y of the semiconductor chip 1 because of hardening/contraction of the resin film 2 so that it is possible to prevent a warp from being generated in the semiconductor chip 1 due to hardening/contraction of the resin 7 covering the circuit formation surface 1X of the semiconductor chip 1.

(4) In the fabrication of the TCP-type semiconductor device 10, a resin film 2 made of thermosetting resin of the epoxy group is stuck on a back surface 20Y facing a circuit formation surface 20X of the semiconductor wafer 20 in a thermal-crimping process. Then, the semiconductor wafer 20 and the resin film 2 are diced to produce semiconductor chips 1 each having a surface protection film 1D and an electrode 1C on a circuit formation surface 1X thereof as well as the resin film 2 attached to a back surface 1Y facing the circuit formation surface 1X. Subsequently, identification marks are formed on the resin film 2 on the back surface 1Y of the semiconductor chip 1 by adopting a laser marking technique. In this configuration, it is now possible to form an identification mark on the side of the back surface 1Y of the semiconductor chip 1 without inflicting an injury on the back surface 1Y of the semiconductor chip 1, that is, on the semiconductor substrate.

(5) The memory module 50 comprises:
TCP-type semiconductor devices 10 each having: a semiconductor chip 1; a resin 7 for covering a circuit formation surface 1X of the semiconductor chip 1; and a resin film 2 for covering a back surface 1Y facing the circuit formation surface 1X of the semiconductor chip 1;
a mounting substrate 51 on which the TCP-type semiconductor devices 10 are mounted; and
cap members 52 attached to the mounting substrate 51 to cover the TCP-type semiconductor devices 10,
wherein the TCP-type semiconductor devices 10 are mounted in a posture so that the back surface 1Y of each of the semiconductor chips 51 is exposed to the cap member 52.

When the cap member 52 is pressed in a process to paste a shipping seal to the cap member 52 during the fabrication of the memory module 50 having the configuration described above, generation of a crack is prevented from originating from a portion with a broken piece of wafer material attached there to since such a piece is prevented from being re-stuck on the back surface 1Y of the semiconductor chip 1. As a result, the yield of the fabrication of the memory modules 50 can be increased.

In the above description, this embodiment is exemplified by a case in which an identification mark is formed by adoption of the laser marking technique. It should be noted, however, that an identification mark can also be formed by using an ink mark technique. In this case, since ink adheres to the resin film 2 better than it adheres to the semiconductor substrate 1A, the identification mark does not peel off with ease.

### Second Embodiment

This embodiment is exemplified by a case in which the present invention is applied to a TCP-type semiconductor device and a CF (Compact Flash) card having the device embedded therein.

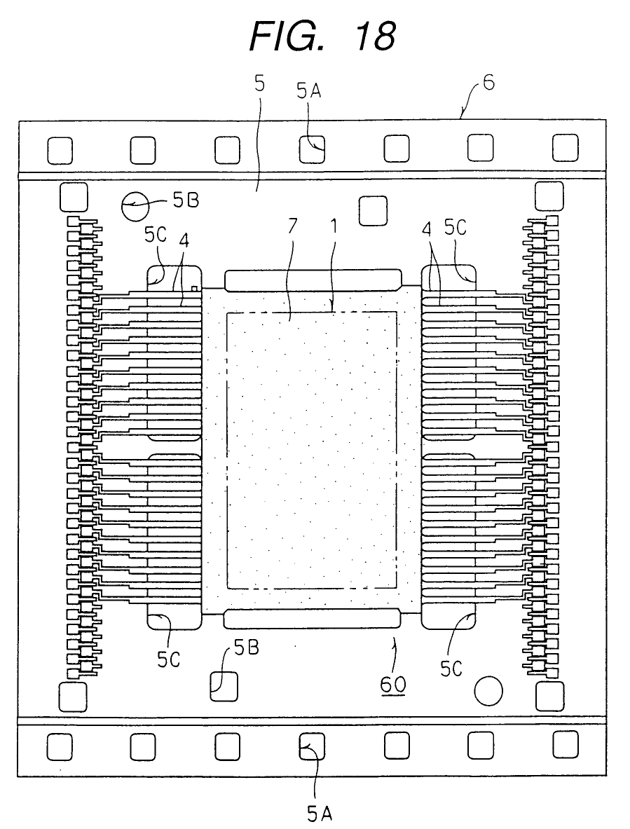

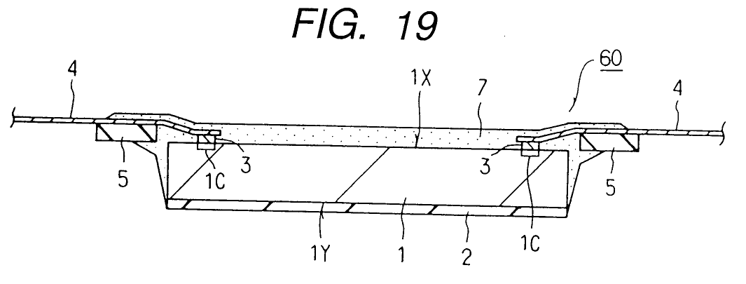

FIG. 18 is a diagram showing a top-view of a TCP-type semiconductor device implemented by the second embodiment of the present invention.

FIG. 19 is a diagram showing a cross section of the device shown in FIG. 18.

As shown in FIGS. 18 and 19, the TCP-type semiconductor device 60 implemented by the second embodiment has basically the same configuration as the first embodiment described above. Differences in configuration between them are as follows.

A plurality of electrodes 1C are laid out along mutually facing long sides of the semiconductor chip 1. In addition, the semiconductor chip 1 includes an embedded EEPROM called a flash memory and is used as a storage circuit system. The TCP-type semiconductor device 60 configured in this way can be manufactured by using the fabrication method for the first embodiment described above.

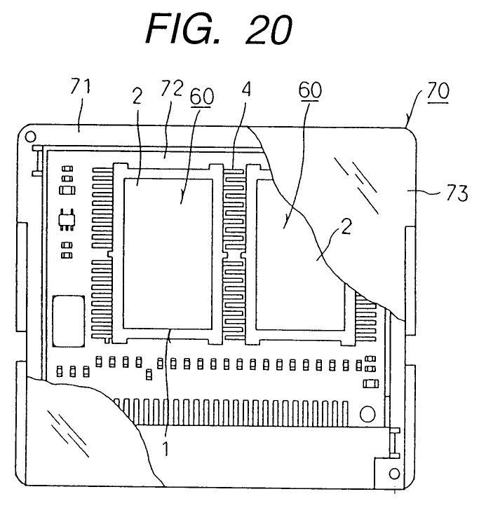

The following description is directed to a CF (Compact Flash) card (an electronic device) 70 in which the TCP-type semiconductor device 60 described above is embedded as shown in FIG. 20.

FIG. 20 is a diagram showing a top-view of the configuration of the CF card 70 including the TCP-type semiconductor device 60.

As shown in FIG. 20, the CF card 70 implemented by this embodiment has a configuration wherein TCP-type semiconductor devices 60 are implemented on two parallel overlapping stages on the front and back surfaces (that is, a main surface and another main surface facing each other) of a mounting substrate 72 and these TCP-type semiconductor devices 60 are covered by metallic cover members 73. The metallic cover members 73 are provided on the front and back surfaces of the mounting substrate 72, being attached to the mounting substrate 72. There are two kinds of TCP-type semiconductor devices 60, namely, those for the upper stage and those for the lower stage. The two kinds of TCP-type semiconductor devices 60 are mounted in a posture so that a back surface 1Y facing a circuit formation surface 1X of each of the semiconductor chips 1 is exposed to the cover member 73. Leads 4 of the TCP-type semiconductor device 60 of either type are formed into a gull-wing type which is one of the known surface mounting types. A lead 4 formed into a gull-wing type comprises a first lead portion extended over the inside and the outside of the semiconductor chip 1, a second lead portion bent from the first lead portion in the thickness direction of the semiconductor chip 1 and a third lead portion extended from the second lead portion in the same direction as the first lead portion. The third lead portion is used as a connection terminal when the TCP-type semiconductor device 60 is mounted on the mounting substrate 72 by soldering. The first lead portion of the lead of the TCP-type semiconductor device 60 at the upper stage is pulled outward by a length greater than the first lead portion of the lead of the TCP-type semiconductor device 60 at the lower stage. In addition, the second lead portion of the lead of the TCP-type semiconductor device 60 at the upper stage is longer than the second lead portion of the lead of the TCP-type semiconductor device 60 at the lower stage.

Next, a method of fabricating the CF card 70 shown in FIG. 18 will be explained with reference to FIGS. 18 and 20.

First of all, the TCP-type semiconductor device 60 is prepared.

Next, one end of each of the leads 4 is cut off and then the lead 4 is formed into a gull-wing type. Subsequently, the flexible film 4 is cut out and the TCP-type semiconductor device 60 is removed from the tape carrier 5. In this way, a TCP-type semiconductor device 60 for the lower stage and a TCP-type semiconductor device 60 for the upper stage are formed.

Then, in a state with the TCP-type semiconductor device 60 for the lower stage and the TCP-type semiconductor device 60 for the upper stage overlapping each other, the third portions of their leads 4 are bonded to the electrode of the mounting substrate 72 by soldering, whereas the TCP-type semiconductor device 60 for the lower stage and the TCP-type semiconductor device 60 for the upper stage are mounted on the front and back surfaces of the mounting substrate 72.

Next, the mounting substrate 72 is installed in a case main body 71 and the cover members 73 are attached to the case main body 71 to cover the TCP-type semiconductor devices 60 and, then, a shipping seal is pasted to the cover member 73 to all but complete the CF card (electronic device) 70.

In this way, the second embodiment is capable of providing the same effects as the first embodiment described earlier.

In addition, the CF card 70 is subjected to an impact test. A CF card 70 passing the impact test will be capable of preventing a crack from being generated in the semiconductor chip 1.

### Third Embodiment

This embodiment is exemplified by a case in which the present invention is applied to a BGA (Ball Grid Array)-type semiconductor device employing a flexible film as a wiring substrate.

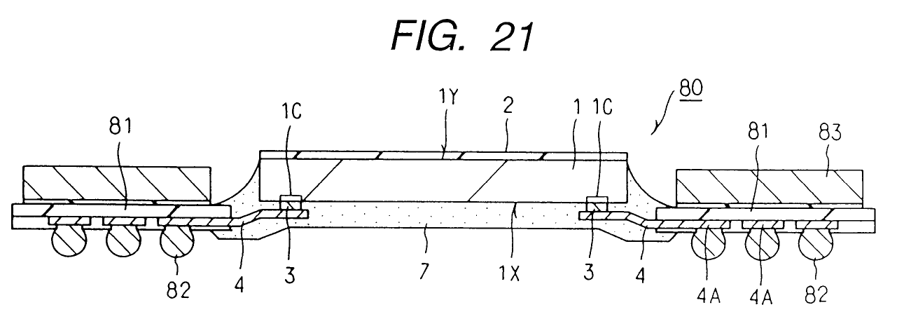

FIG. 21 is a diagram showing a cross-sectional view of the configuration of the BGA-type semiconductor device implemented by the third embodiment of the present invention.

As shown in FIG. 21, the BGA-type semiconductor device 80 implemented by the third embodiment has a configuration comprising a semiconductor chip 21, a resin 7 covering a circuit formation surface 1X of the semiconductor chip 1, a flexible film 81 having leads 4 and lands 4A formed on one main surface thereof, a strengthening member 83 attached to another main surface of the flexible film 81 facing the main surface through an insulating adhesive agent, bumps 82 each having a ball shape and sticking to one of the lands 4A and a resin film 2 attached to a rear surface 1Y of the semiconductor chip 1 to cover the rear surface 1Y. One end of each of the leads 4 is electrically connected to an electrode 1C of the semiconductor chip 1 through one of the bumps 3, whereas the other end of the lead 4 forms a single body with one of the lands 4A. The resin 7 is created by adopting a potting method.

As described above, the BGA-type semiconductor device 80 implemented by the third embodiment has a configuration wherein the circuit formation surface 1X of the semiconductor chip 1 is covered by the resin 7. Thus, by attaching the resin film 2 to the rear surface 1Y of the semiconductor chip 1 to cover the rear surface 1Y, it is possible to obtain the same effects as the first embodiment described earlier.

### Fourth Embodiment

This embodiment is exemplified by a case in which the present invention is applied to a CSP (Chip Size Package)-type semiconductor device employing a flexible film as a wiring substrate.

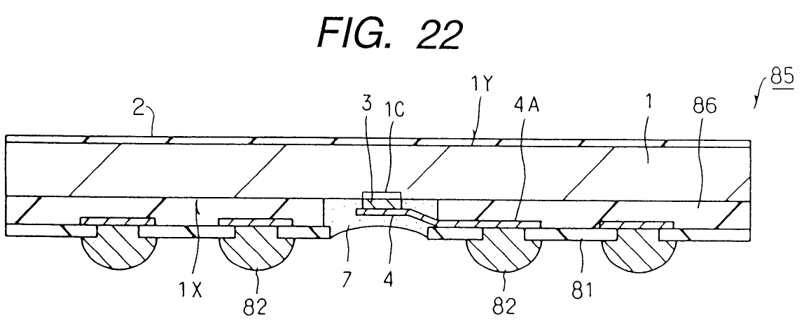

FIG. 22 is a diagram showing a cross-sectional view of the configuration of the CSP-type semiconductor device implemented by the fourth embodiment of the present invention.

As shown in FIG. 22, the CSP-type semiconductor device 85 implemented by this embodiment has a configuration comprising a semiconductor chip 1, a resin 7 covering a circuit formation surface 1X of the semiconductor chip 1, a flexible film 81 having leads 4 and lands 4A formed on one main surface thereof, an elastomer 86 interposed between the flexible film 81 and the main surface of the semiconductor chip 1 and a resin film 2 attached to a rear surface 1Y of the semiconductor chip 1 to cover the rear surface 1Y. One end of each of the leads 4 is electrically connected to the electrode 1C of the semiconductor chip 1 through one of the bumps 3, whereas the other end of the lead 4 forms a single body with one of the lands 4A. One of the surfaces of the elastomer 86 is firmly bonded to the circuit formation surface 1X of the semiconductor chip 1, while the other surface is bonded to a main surface of the flexible film 81. The elastomer 86 is typically made of low-elasticity resin of the epoxy or silicon group.

As described above, since the CSP-type semiconductor device 85 has a configuration wherein the circuit formation surface 1X of the semiconductor chip 1 is covered by the resin 7 and the elastomer 86, the same effects as the first embodiment can be obtained since the resin film 2 is attached to a rear surface 1Y of the semiconductor chip 1 to cover the rear surface 1Y.

The present invention has been exemplified by various embodiments. It should be noted that the present invention is not limited to the embodiments described and illustrated herein. A variety of changes can of course be made to the embodiments so long as the changes do not depart from the essence of the present invention.

For example, the present invention can also be applied to a bare-chip mounting technology for mounting a semiconductor chip on a mounting substrate in a bare state.

In addition, the present invention can also be applied to a technology for fabricating a semiconductor device wherein relocation leads and a seal resin layer are formed on a surface protection film on a circuit formation surface of the semiconductor chip at a semiconductor-wafer stage.

It is possible to prevent a crack from being generated in the semiconductor chip.

It is thus possible to increase a manufacturing yield of the semiconductor device.

As a result, it is also possible to increase the manufacturing yield of the electronic device.

1. A method of manufacturing a semiconductor device comprising the steps of:
(a) providing a semiconductor wafer having a main surface, a rear surface opposite to said main surface and a resin film to cover said main surface, said semiconductor wafer including a plurality of chip forming areas defined by scribe lines, each of said plurality of chip forming areas having a plurality of semiconductor elements and bonding pads formed on said main surface thereof;
(b) after the step (a), forming an insulating layer, from material under a tape condition, on said rear surface of said semiconductor wafer, said insulating layer being formed during the wafer state in the manufacture of the device and extended over the entirety of said rear surface of said semiconductor wafer, said insulating layer being formed after the formation of said resin film on said main surface;
(c) after the step (b), dividing said semiconductor wafer along said scribe lines, thereby to form a plurality of chips, each having said plurality of semiconductor elements, said bonding pads, a part of said resin film and a part of said insulating layer.

2. A method of manufacturing a semiconductor device according to claim 1, further comprising a step of forming a plurality of bump electrodes on said resin film of each of said plurality of chips, and wherein said plurality of bump electrodes are electrically connected to the corresponding bonding pads of said plurality of chips.

3. A method of manufacturing a semiconductor device according to claim 2, wherein each of said plurality of chips together with said plurality of bump electrodes is a chip size package to be mounted on a printed circuit board via said plurality of bump electrodes.

4. A method of manufacturing a semiconductor device according to claim 1, wherein said dividing said semiconductor wafer in the step (c) is performed by dicing in which said semiconductor wafer and said insulating layer on said rear surface thereof are split simultaneously so as to divide the chip forming areas into said plurality of chips, respectively.

5. A method of manufacturing a semiconductor device according to claim 1, further comprising a step of forming wiring layers on said main surface of said semiconductor wafer in the step (a), wherein said wiring layers are electrically connected to the corresponding bonding pads of said plurality of chips, and wherein said part of said resin film covers said wiring layers in each of said plurality of chips.

6. A method of manufacturing a semiconductor device comprising providing a semiconductor wafer having a main surface, a rear surface and a resin film over said main surface, said semiconductor wafer including a plurality of chip forming areas having a plurality of semiconductor elements and bonding pads formed on said main surface thereof;
forming an insulating layer, from material provided under a tape condition, on said rear surface of said semiconductor wafer, said insulating layer being formed during the wafer state in the manufacture of the device and extended over the entirety of said rear surface of said semiconductor wafer, said insulating layer being formed after the formation of said resin film on said main surface;
after forming said insulating layer on said rear surface, dividing said semiconductor wafer to form a plurality of chips, each of said plurality of chips having at least one semiconductor element, at least one bonding pad, a part of said resin film and a part of said insulating layer.

7. A method of manufacturing a semiconductor device according to claim 6, further comprising forming a plurality of bump electrodes on said resin film of each of said plurality of chips such that said plurality of bump electrodes are electrically connected to corresponding bonding pads of said plurality of chips.

8. A method of manufacturing a semiconductor device according to claim 7, wherein each of said plurality of chips and ones of said plurality of bump electrodes comprise a chip size package to be mounted on a printed circuit board via said plurality of bump electrodes.

9. A method of manufacturing a semiconductor device according to claim 6, wherein dividing said semiconductor wafer comprises dicing said semiconductor wafer in which said semiconductor wafer and said insulating layer on said rear surface thereof are split simultaneously so as to divide the chip forming areas into said plurality of chips, respectively.

10. A method of manufacturing a semiconductor device according to claim 9, wherein providing said semiconductor wafer comprises forming wiring layers on said main surface such that said wiring layers are electrically connected to the corresponding bonding pads of said plurality of chips, and wherein said part of said resin film covers said wiring layers in each of said plurality of chips.

11. A semiconductor device comprising:
a mounting substrate having a plurality of wiring layers and a plurality of electrode pads formed on one surface thereof;
a tape carrier package having:
a flexible film having a hole of rectangular shape;
a semiconductor chip having a circuit forming surface and a back surface opposite to said circuit forming surface, said semiconductor chip having a plurality of semiconductor elements and electrodes formed on said circuit forming surface and being disposed in said hole of said flexible film;
a plurality of leads disposed on said flexible film, one end of each of said plurality of leads extending on said circuit forming surface of said semiconductor chip and being electrically connected to said electrodes of said semiconductor chip, the other ends of each of said plurality of leads extending outwardly from said flexible film to provide outer leads; and
a resin member sealing said circuit forming surface of said semiconductor chip and said one ends of said plurality of leads;
said tape carrier package being mounted on said one surface of said mounting substrate such that said outer leads of said plurality of leads are soldered to said electrode pads of said mounting substrate and said circuit forming surface of said semiconductor chip faces said one surface of said mounting substrate;
a cover member attached to said mounting substrate to cover said tape carrier package, such that an inner surface of said cover member is positioned at a vicinity of said back surface of said semiconductor chip of said tape carrier package; and
an insulating tape member formed to cover said back surface of said semiconductor chip and being disposed between said back surface of said semiconductor chip and said inner surface of said cover member.

12. A semiconductor device according to claim 11, wherein said insulating tape member has a thickness thinner than a thickness of said resin member covering said circuit forming surface of said semiconductor chip in a thickness direction of said semiconductor chip.

13. A semiconductor device according to claim 12, wherein said resin member includes a potting resin applied by a dispenser and said insulating tape member includes an adhesive sheet of resin.

14. A semiconductor device according to claim 13, wherein said cover member is formed of a metallic plate, and wherein said insulating tape member electrically isolates said semiconductor chip from said metallic plate.

15. A semiconductor device according to claim 14, wherein said back surface of said semiconductor chip is mechanically protected by said insulating tape member.

16. A semiconductor device according to claim 15, wherein a size of said insulating tape member is substantially the same as a size of said semiconductor chip.

17. A semiconductor device comprising:
a mounting substrate having a plurality of wiring layers and a plurality of electrode pads formed on one surface thereof;
a tape carrier package having:
a flexible film having a hole;
a semiconductor chip having a first surface and a second surface opposite to said first surface, said semiconductor chip having a plurality of semiconductor elements and electrodes formed on said first surface and being disposed in said hole of said flexible film;
a plurality of leads disposed on said flexible film, one end of each of said plurality of leads extending from said first surface of said semiconductor chip and being electrically connected to said electrodes of said semiconductor chip, the other ends of each of said plurality of leads providing outer leads; and
a resin member sealing said first surface of said semiconductor chip and said one ends of said plurality of leads;
said tape carrier package being mounted on said one surface of said mounting substrate such that said outer leads are attached to said electrode pads of said mounting substrate and said first surface of said semiconductor chip faces said one surface of said mounting substrate;
a cover member to cover said tape carrier package such that an inner surface of said cover member is positioned at a vicinity of said second surface of said semiconductor chip; and
an insulating tape member formed to cover said second surface of said semiconductor chip and being disposed between said back surface of said semiconductor chip and said inner surface of said cover member.

18. A semiconductor device according to claim 17, wherein said insulating tape member has a thickness thinner than a thickness of said resin member covering said first surface of said semiconductor chip in a thickness direction of said semiconductor chip.

19. A semiconductor device according to claim 18, wherein said resin member includes a potting resin applied by a dispenser and said insulating tape member includes an adhesive sheet of resin.

20. A semiconductor device according to claim 19, wherein said cover member is formed of a metallic plate, and wherein said insulating tape member electrically isolates said semiconductor chip from said metallic plate.

21. A semiconductor device according to claim 20, wherein said second surface of said semiconductor chip is mechanically protected by said insulating tape member.

22. A semiconductor device according to claim 21, wherein a size of said insulating tape member is substantially the same as a size of said semiconductor chip.
